(19) United States
(12) Patent Application Publication
(10) Pub. No.: US 2026/0173304 A1
(43) Pub. Date: Jun. 18, 2026

(54) HEAT DISSIPATION DEVICE

(71) Applicant: ZHENG-JEI LIN, Kaohsiung City (TW)

(72) Inventor: ZHENG-JEI LIN, Kaohsiung City (TW)

(21) Appl. No.: 19/413,604

(22) Filed: Dec. 9, 2025

(30) Foreign Application Priority Data
Dec. 17, 2024 (TW) 113149189

(51) Int. Cl. H05K 7/20

(52) U.S. Cl. CPC H05K 7/20145; H05K 7/20154

(57) ABSTRACT

A heat dissipation system includes a first heat-exchange plate, having a first gas flow groove disposed on one side; a main body, having a first penetrating portion, a second penetrating portion, a third penetrating portion forming an insertion space on the main body, and a charging valve; a first guiding plate, having one side thereof provided with a second gas flow groove; a second guiding plate, having one side thereof provided with a third gas flow groove, and another side thereof provided with a fourth gas flow groove; and a compressor, disposed in the insertion space. The compressor includes a compression chamber, which has a compression space therein, and a gas inlet and a gas outlet in communication with the compression space; a motor; a rotation shaft; and a rotor. The first, second, third, and fourth gas flow grooves and the compression space are in communication with each other.

### BACKGROUND OF THE DISCLOSURE

### 1. Field of the Disclosure

The present disclosure relates to heat dissipation systems, and more particularly, to a heat dissipation system for dissipating heat from an electronic heat generation source.

### 2. Description of the Related Art

A water-cooling device is one of the mainstream heat dissipation devices used for dissipating heat from an electronic heat generation source. Since the water-cooling device performs heat dissipation circulation by using liquid, the installation and maintenance costs thereof are relatively high. Also, if it installation or operation of it is improperly performed, liquid leakage may occur, so as to affect the heat dissipation performance, and the leaked liquid may further damage internal hardware components of a computer. In addition, the cooling liquid used for cooling the electronic heat generation source may evaporate or deteriorate after a long-term use, and the water pump may also malfunction, so as to affect the heat dissipation performance and stability of the overall system. In view of the issues above, a heat dissipation system capable of performing high-efficiency cooling and reliable operation with a low maintenance requirement is highly desirable.

### SUMMARY OF THE DISCLOSURE

The present disclosure aims at providing a heat dissipation system capable of performing high-efficiency cooling and reliable operation with a maintenance requirement is highly desirable.

For achieving the aforementioned objectives, the present disclosure provides a heat dissipation system, comprising:
a first heat-exchange plate, having a first gas flow groove disposed on one side thereof;
a main body, having one side thereof connected with one side of the first heat-exchange plate on which the first gas flow groove is disposed, the main body comprising:
   a first penetrating portion, extending through two opposite sides of the main body and having one end thereof in communication with one end of the first gas flow groove;
   a second penetrating portion, extending through the two opposite sides of the main body and having one end thereof in communication with another end of the first gas flow groove;
   a third penetrating portion, extending through two opposite ends of the main body and forming an insertion space on the main body; and
   a charging valve, disposed on one end of the main body and in communication with the first penetrating portion;
a first guiding plate, having one side thereof connected with one side of the main body opposite to the first heat-exchange plate, a second gas flow groove disposed on the side of the first guiding plate contacting the main body, one end of the second gas flow groove being in communication with one end of the first penetrating portion opposite to the first heat-exchange plate, another end of the second gas flow groove being in communication with one side of the first guiding plate opposite to the main body;
a second guiding plate, having one side thereof connected with the side of the first guiding plate opposite to the main body, the second guiding plate comprising:
   a third gas flow groove, disposed on the side of the second guiding plate connected with the first guiding plate, one end of the third gas flow groove being in communication with the end of the second gas flow groove opposite to the first penetrating portion; and
   a fourth gas flow groove, disposed on one side of the second guiding plate opposite to the first guiding plate, one end of the fourth gas flow groove being in communication with one end of the second penetrating portion opposite to the first heat-exchange plate;
a second heat-exchange plate, disposed on the side of the second guiding plate opposite to the first guiding plate, so as to cover the fourth gas flow groove; and
a compressor, disposed in the insertion space and comprising:
   a compression chamber, having a compression space therein, a gas inlet and a gas outlet being sequentially disposed on an outer side of the compression chamber, the gas inlet being in communication with one end of the third gas flow groove opposite to the second gas flow groove, the gas outlet being in communication with one end of the fourth gas flow groove opposite to the second penetrating portion;
   a motor, disposed in the compression chamber;
   a rotation shaft, having one end thereof connected with the motor, and another end thereof extending into the compression space, the rotation shaft being rotatably disposed on one side of the compression chamber contacting the compression space; and
a rotor, disposed in the compression space and connected with the rotation shaft, the rotation shaft being configured to rotate together with the rotor, so as to compress a gas fluid in the compression space, and deliver a compressed gas fluid from the gas outlet toward the fourth gas flow groove.

Preferably, the compressor further comprises a stator, which is non-rotatably disposed in the compression space and arranged between the rotor and the motor, wherein the stator, the rotor, and an axis of the rotation shaft are disposed in a coaxial arrangement.

Preferably, the rotor comprises a rotor disc disposed on the rotation shaft, and a plurality of rotor blades; wherein each of the rotor blades is radially disposed around an outer peripheral side of the rotor disc, and a surface of each of the rotor blades is disposed in a twisted first arc surface; and the stator comprises a stator disc through which the rotation shaft passes, and a plurality of stator blades; wherein each of the stator blades is radially disposed around an outer peripheral side of the stator disc, and a surface of each of the stator blades is disposed in a twisted second arc surface; wherein a twisting direction of the first arc surface is opposite to a twisting direction of the second arc surface.

Preferably, a recess is disposed on one side of the first heat-exchange plate opposite to the main body.

Preferably, a plurality of fins are disposed on one side of the second heat-exchange plate opposite to the second guiding plate, wherein the fins are disposed on the second heat-exchange plate at equal intervals along an extending direction.

Preferably, a fan is disposed on one side of the second heat-exchange plate opposite to the second guiding plate.

Preferably, an atomizer is disposed on one end of the second penetrating portion opposite to the first guiding plate.

Preferably, a seal plate is disposed on the main body and arranged in positional alignment with the third penetrating portion, so as to cover the insertion space.

Preferably, the charging valve is selectively connected to a gas exhaust device, so as to create a vacuum in the compression space, or connected to a refrigerant storage device, so as to fill the compression space with a refrigerant.

Preferably, the heat dissipation system further comprises:
a first through hole passing through the first guiding plate to communicate two corresponding sides of the first guiding plate and arranged in communication with the third gas flow groove;
a second through hole passing through the main body and disposed in positional alignment with the first through hole and the gas inlet, so that the side of the main body opposite to the first heat-exchange plate is in communication with the insertion space and the compression space;
a third through hole passing through the main body and disposed in positional alignment with the gas outlet, so that the side of the main body opposite to the first heat-exchange plate is in communication with the insertion space and the compression space;
a fourth through hole passing through the first guiding plate to communicate the two opposite sides of the first guiding plate and disposed in positional alignment with the third through hole;
a fifth through hole passing through the second guiding plate to communicate two opposite sides of the second guiding plate, disposed in positional alignment with the fourth through hole, and arranged in communication with the fourth gas flow groove; and
a sixth through hole passing through the first guiding plate to communicate the two opposite sides of the first guiding plate, and disposed in positional alignment with the fourth gas flow groove and the second penetrating portion.

With such configuration, as compared with prior arts, the present disclosure achieves following technical effects. The present disclosure utilizes the compressor to unidirectionally drive the refrigerant flow, so that the refrigerant, after being compressed and heated, first exchanges heat with the second heat-exchange plate and is cooled by the second heat-exchange plate, and then the cooled refrigerant exchanges heat with the first heat-exchange plate, thereby repeating such operation cycle to reuse the refrigerant, achieving a high-efficiency heat dissipation and a stable circulation. Also, since the refrigerant is delivered in a gaseous state, and the flow path for delivering the refrigerant is enclosed and light-shielded, the present disclosure ensures that the refrigerant does not deteriorate after a long-term and repeated circulation. Further, replacement of the refrigerant is performed through vacuuming and filling without the need of disassembling components, thereby ensuring the sealing of the refrigerant, preventing leakage of the refrigerant, and reducing maintenance costs thereof.

### BRIEF DESCRIPTION OF THE DRAWINGS

FIG. 1A to FIG. 1C are a series of exploded views illustrating the structural features of the heat dissipation system in accordance with an embodiment of the present disclosure.

FIG. 2A to FIG. 2C are a series of structural perspective views illustrating structural features of the compressor in accordance with an embodiment of the present disclosure.

### DETAILED DESCRIPTION OF THE DISCLOSURE

The aforementioned and further advantages and features of the present disclosure will be understood by reference to the description of the preferred embodiment in conjunction with the accompanying drawings where the components are illustrated based on a proportion for explanation but not subject to the actual component proportion.

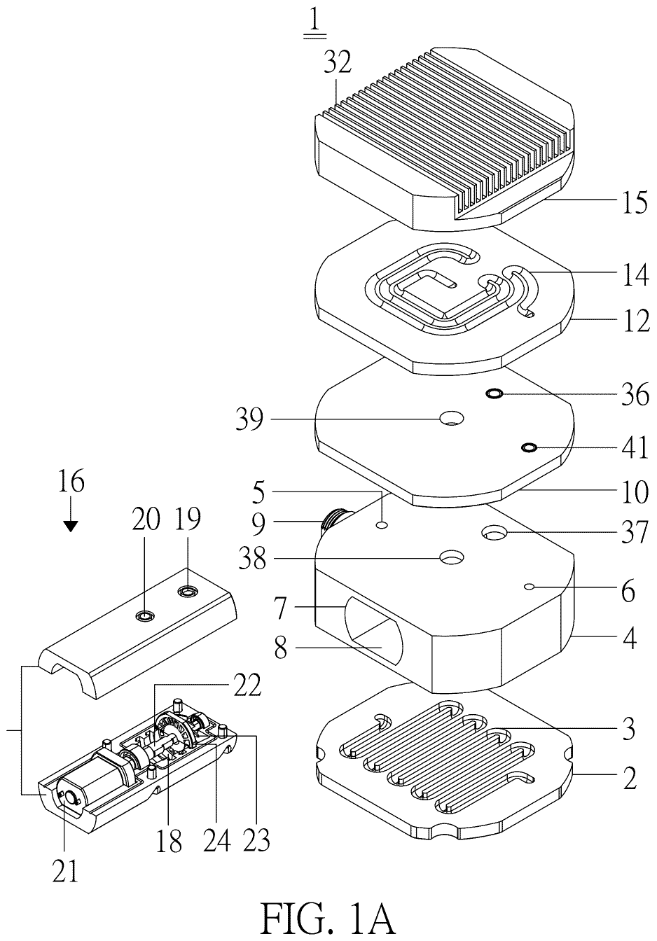

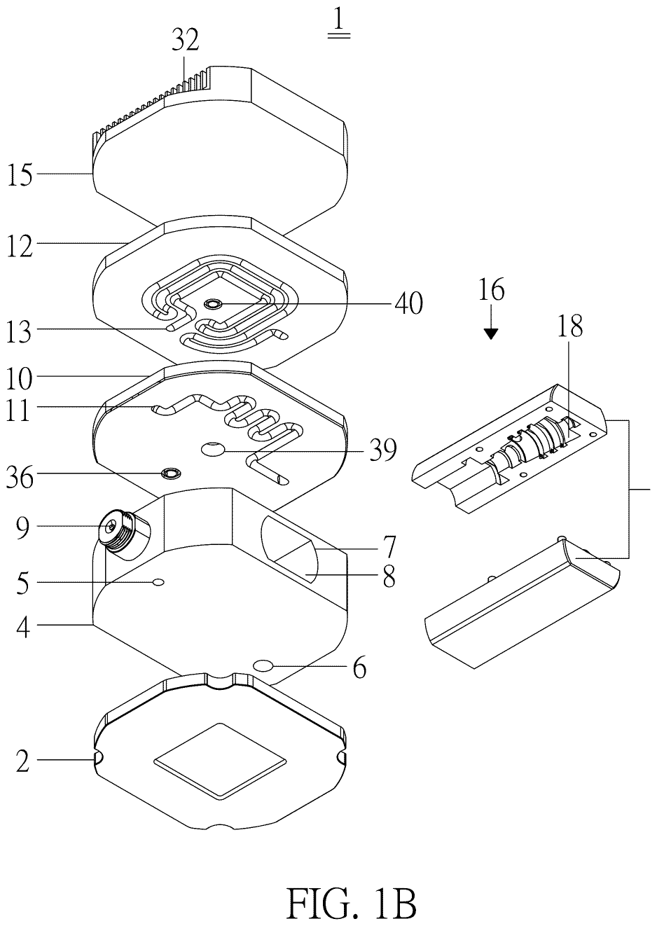

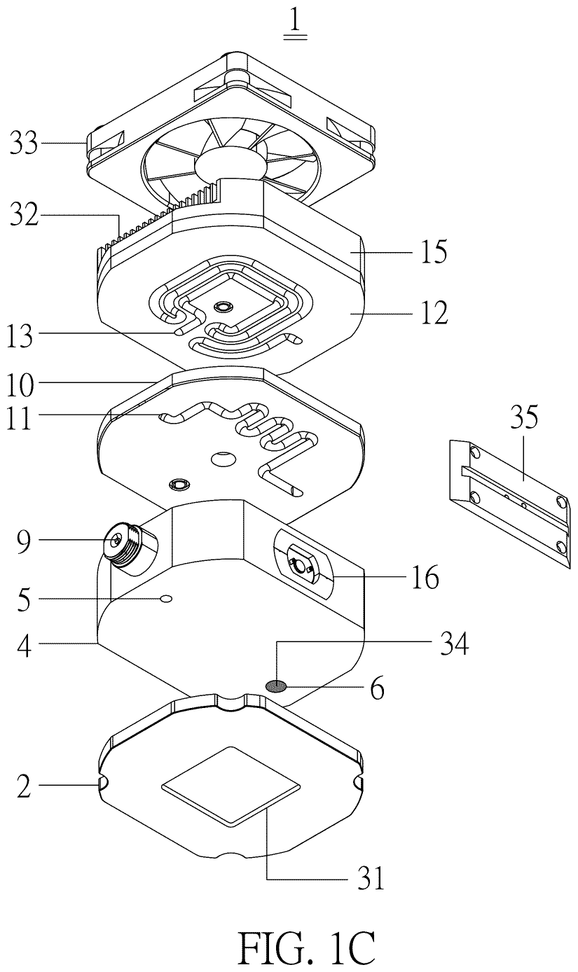

Referring to FIG. 1A to FIG. 1C, the present disclosure provides a heat dissipation system 1, comprising a first heat-exchange plate 2, a main body 4, a first guiding plate 10, a second guiding plate 12, a second heat-exchange plate 15, and a compressor 16. The first heat-exchange plate 2 has a first gas flow groove 3 disposed on one side thereof. The main body 4 has one side thereof connected with one side of the first heat-exchange plate 2 on which the first gas flow groove 3 is disposed. The main body 4 comprises a first penetrating portion 5, extending through two opposite sides of the main body 4 and having one end of the first penetrating portion 5 in communication with one end of the first gas flow groove 3; a second penetrating portion 6, extending through the two opposite sides of the main body 4 and having one end of the second penetrating portion 6 in communication with another end of the first gas flow groove 3; a third penetrating portion 7, extending through two opposite ends of the main body 4 and forming an insertion space 8 on the main body 4; and a charging valve 9, disposed on one end of the main body 4 and in communication with the first penetrating portion 5. The first guiding plate 10 has one side thereof connected with one side of the main body 4 opposite to the first heat-exchange plate 2, a second gas flow groove 11 disposed on the side of the first guiding plate 10 contacting the main body 4, with one end of the second gas flow groove 11 being in communication with one end of the first penetrating portion 5 opposite to the first heat-exchange plate 2, and another end of the second gas flow groove 11 being in communication with one side of the first guiding plate 10 opposite to the main body 4. The second guiding plate 12 has one side thereof connected with the side of the first guiding plate 10 opposite to the main body 4. The second guiding plate comprises a third gas flow groove 13, disposed on the side of the second guiding plate 12 connected with the first guiding plate 10, with one end of the third gas flow groove 13 being in communication with the end of the second gas flow groove 11 opposite to the first penetrating portion 5; and a fourth gas flow groove 14, disposed on one side of the second guiding plate 12 opposite to the first guiding plate 10, with one end of the fourth gas flow groove 14 being in communication with one end of the second penetrating portion 6 opposite to the first heat-exchange plate 2. The second heat-exchange plate 15 is disposed on the side of the second guiding plate 12 opposite to the first guiding plate 10, so as to cover the fourth gas flow groove 14. The compressor 16 is disposed in the insertion space 8. The compressor 16 comprises a compression chamber 17, a motor 21, a rotation shaft 22, and a rotor 23. The compression chamber 17 has a compression space 18 therein, with a gas inlet 19 and a gas outlet 20 being sequentially disposed on an outer side of the compression chamber 17. The gas inlet 19 is in communication with one end of the third gas flow groove 13 opposite to the second gas flow groove 11. The gas outlet 20 is in communication with one end of the fourth gas flow groove 14 opposite to the second penetrating portion 6. The motor 21 is disposed in the compression chamber 17. The rotation shaft 22 has one end thereof connected with the motor 21, and the other end thereof extending into the compression space 18. The rotation shaft 22 is rotatably disposed on one side of the compression chamber 17 contacting the compression space 18. The rotor 23 is disposed in the compression space 18 and connected with the rotation shaft 22. The rotation shaft 22 is configured to rotate together with the rotor 23, so as to compress the gas fluid in the compression space 18, and deliver a compressed gas fluid from the gas outlet 20 toward the fourth gas flow groove 14.

Preferably, after compressing the gas fluid, to allow the rotor 23 to forwardly deliver the compressed gas fluid for preventing the compressed gas fluid from backflowing toward the rotor 23 and causing squeezing, thereby reducing the compression efficiency of the gas in the compression space 18, the compressor 16 further comprises a stator 24, which is non-rotatably disposed in the compression space 18 and arranged between the rotor 23 and the motor 21, wherein the stator 24, the rotor 23, and the axis of the rotation shaft 22 are disposed in a coaxial arrangement.

Preferably, for the heat dissipation system 100 to be disposed at a position corresponding to an electronic heat generation source, so as to perform heat exchange with the electronic heat generation source and thereby dissipate heat and cool the electronic heat generation source, a recess 31 is disposed on one side of the first heat-exchange plate 2 opposite to the main body 4. Understandably, the recess 31 is configured to contact a computer processor, such as a CPU or an NPU, so as to achieve a highly efficient heat dissipation effect and ensure the operation performance of the processor. In a preferred embodiment, the electronic heat generation source refers to an electronic heat generation component or a heat generating point on the electronic heat generation component, but is not limited thereto.

Preferably, since the gas fluid is heated after being compressed by the rotor 23, the high-temperature compressed gas fluid is delivered to the fourth gas flow groove 14 for heat dissipation and cooling, and the cooled compressed gas fluid is then delivered to the first gas flow groove 3 to cool the electronic heat generation source, repeating the use of the compressed gas fluid to achieve a cooling cycle. In order to enhance the heat dissipation effect of the compressed gas fluid in the fourth gas flow groove 14 for achieving an efficient cooling operation, a plurality of fins 32 are disposed on one side of the second heat-exchange plate 15 opposite to the second guiding plate 12, wherein the fins 32 are disposed on the second heat-exchange plate 15 at equal intervals along an extending direction. In a preferred embodiment, to further enhance the cooling effect upon the compressed gas fluid in the fourth gas flow groove 14, a fan 33 is disposed on one side of the second heat-exchange plate 15 opposite to the second guiding plate 12.

Preferably, to allow the cooled compressed gas fluid to rapidly and evenly diffuse, so as to fill the first gas flow groove 3 and efficiently perform the heat exchange operation with the electronic heat generation source, an atomizer 34 is disposed on one end of the second penetrating portion 6 opposite to the first guiding plate 10.

Preferably, to ensure that the compressor 16 is stably positioned without displacement, thereby preventing leakage of the gas fluid in the compression space 18, a seal plate 35 is disposed on the main body 4 and arranged in positional alignment with the third penetrating portion 7, so as to cover the insertion space 8.

Preferably, to enhance the heat dissipation efficiency and meet the cooling requirements of high-power electronic heat generation sources, the compression space 18 is allowed to be filled with a refrigerant. Also, in order to ensure that no impurities or contaminated gas are present in the compression space 18, so that the refrigerant, after being filled into the compression space 18 and compressed by the rotor 23, is able to stably and durably maintain its heat dissipation performance without undergoing deterioration, the charging valve 9 is selectively connected to a gas exhaust device, so as to create a vacuum in the compression space 18, or connected to a refrigerant storage device, so as to fill the compression space with the refrigerant. Particularly, after the refrigerant is filled from the charging valve 9 into the first penetrating portion 5, the refrigerant sequentially flows through the second gas flow groove 11 and the third gas flow groove 13 to be delivered from the gas inlet 19 into the compression space 18, and then sequentially flows through the gas outlet 20 to the fourth gas flow groove 14, the second penetrating portion 6, and the first gas flow groove 3, before returning to the first penetrating portion 5, completing a circulation of cooling path. Further, to ensure that the refrigerant flows along the designated circulation path, thereby achieving a repeated heat exchange circulation, the rotor 23 is utilized for compressing the refrigerant and generating the compressed gas fluid.

Preferably, to ensure the smooth delivery of the refrigerant, the heat dissipation system 1 further comprises a first through hole 36, a second through hole 37, a third through hole 38, a forth through hole 39, a fifth through hole 40, and a sixth through hole 41. The first through hole 36 passes through the first guiding plate 10 to communicate two corresponding sides of the first guiding plate 10 and arranged in communication with the third gas flow groove 13. The second through hole 37 passes through the main body 4 and is disposed in positional alignment with the first through hole 36 and the gas inlet 19, so that the side of the main body 4 opposite to the first heat-exchange plate 2 is in communication with the insertion space 8 and the compression space 18. The third through hole 38 passes through the main body 4 and is disposed in positional alignment with the gas outlet 20, so that the side of the main body 4 opposite to the first heat-exchange plate 2 is in communication with the insertion space 8 and the compression space 18. The fourth through hole 39 passes through the first guiding plate 10 to communicate the two opposite sides of the first guiding plate 10 and is disposed in positional alignment with the third through hole 38. The fifth through hole 40 passes through the second guiding plate 12 to communicate two opposite sides of the second guiding plate 12, and is disposed in positional alignment with the fourth through hole 39, and arranged in communication with the fourth gas flow groove 14. The sixth through hole 41 passes through the first guiding plate 10 to communicate the two opposite sides of the first guiding plate 10, and is disposed in positional alignment with the fourth gas flow groove 14 and the second penetrating portion 6.

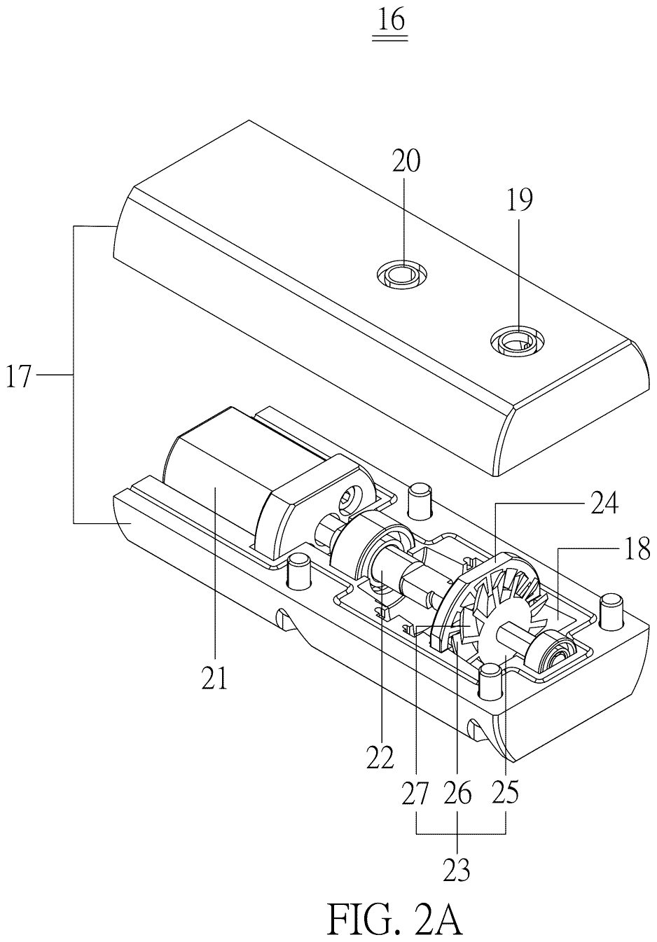

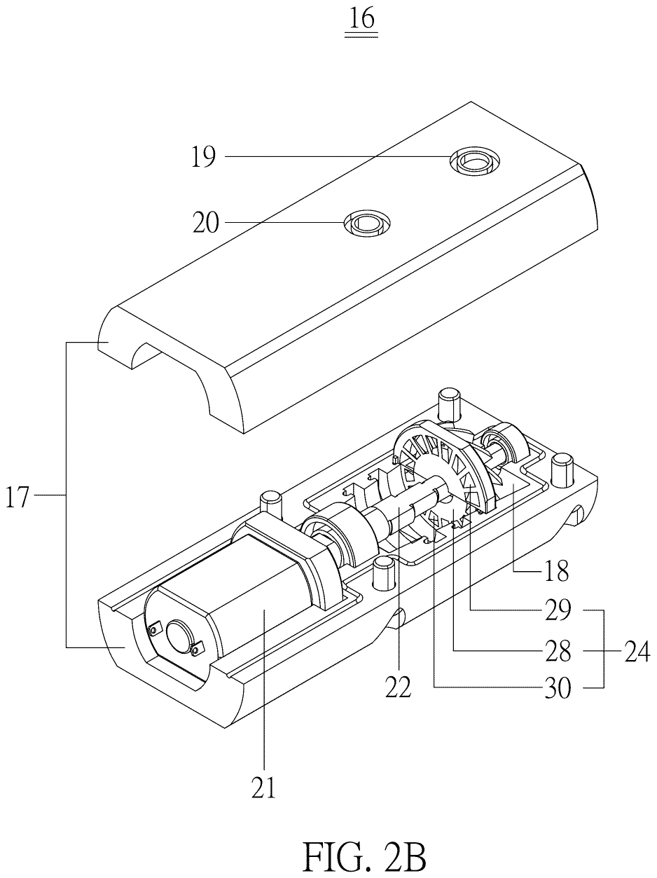

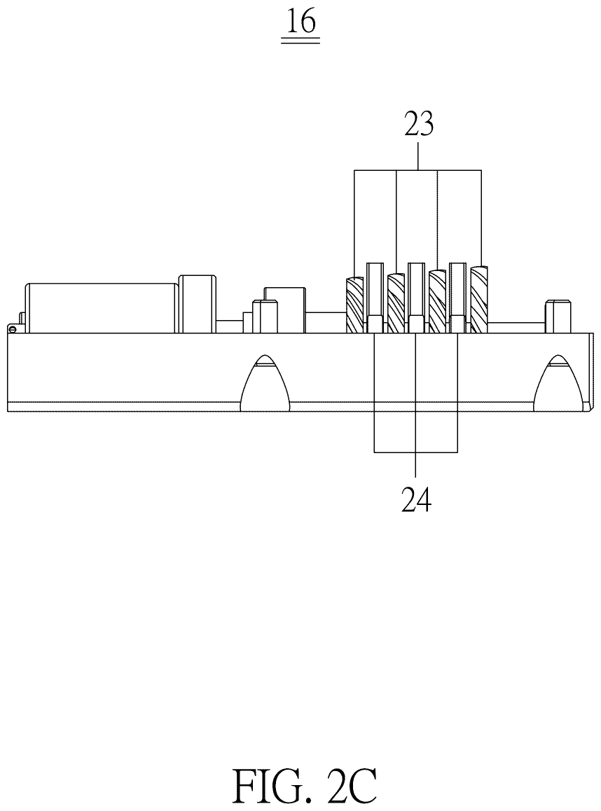

Preferably, to effectively prevent backflow of the compressed gas fluid, so as to ensure that the compressed gas fluid is forwardly delivered to the fourth gas flow groove 14 for performing the heat exchange operation with the second heat-exchange plate 15, referring to FIG. 2A to FIG. 2C, the rotor 23 comprises a rotor disc 25 disposed on the rotation shaft 22, and a plurality of rotor blades 26. Each of the rotor blades 26 is radially disposed around an outer peripheral side of the rotor disc 25, and a surface of each of the rotor blades 26 is disposed in a twisted first arc surface 27. Also, the stator 24 comprises a stator disc 28 through which the rotation shaft 22 passes, and a plurality of stator blades 29. Each of the stator blades 29 is radially disposed around an outer peripheral side of the stator disc 28, and a surface of each of the stator blades 29 is disposed in a twisted second arc surface 30. Therein, the twisting direction of the first arc surface 27 is opposite to the twisting direction of the second arc surface 30. In a preferred embodiment, to enhance the efficiency of the compressed gas fluid and prevent the backflow of it, as shown by FIG. 2C, the present disclosure is allowed to comprises a plurality of rotors 23 and a plurality of stators 24, and the rotors 23 and the stators 24 are alternately arranged.

Compared with prior arts, the present disclosure achieves following technical features. The present invention utilizes the compressor 16 to unidirectionally drive the flow of refrigerant, allowing the refrigerant which is heated through compression, to first exchange heat and be cooled by the second heat-exchange plate 15, and then, after being cooled, to exchange heat with the first heat-exchange plate 2, so as to repeatedly circulate the refrigerant to achieve a high-efficiency heat dissipation operation and a stable circulation thereof. Moreover, since the refrigerant is delivered in a gaseous state, and the flow path for delivering the refrigerant is enclosed and light-shielded, the present disclosure ensures that the refrigerant does not deteriorate even after a long-term repeated circulation, and the refrigerant is replaceable by vacuuming and filling without disassembling the components, thereby ensuring the sealing of the refrigerant, preventing leakage, and further reducing maintenance costs.

Although particular embodiments of the disclosure have been described in detail for purposes of illustration, various modifications and enhancements may be made without departing from the scope of the disclosure. Accordingly, the disclosure is not to be limited except as by the appended claims. Also, the terms “first,” “second,” and the like as used in the specification are solely used for identifying components, and are not intended to limit the upper or lower number of the relative components.

1. A heat dissipation system, comprising:
a first heat-exchange plate, having a first gas flow groove disposed on one side thereof;
a main body, having one side thereof connected with one side of the first heat-exchange plate on which the first gas flow groove is disposed, the main body comprising:
a first penetrating portion, extending through two opposite sides of the main body and having one end thereof in communication with one end of the first gas flow groove;
a second penetrating portion, extending through the two opposite sides of the main body and having one end thereof in communication with another end of the first gas flow groove;
a third penetrating portion, extending through two opposite ends of the main body and forming an insertion space on the main body; and
a charging valve, disposed on one end of the main body and in communication with the first penetrating portion;
a first guiding plate, having one side thereof connected with one side of the main body opposite to the first heat-exchange plate, a second gas flow groove disposed on the side of the first guiding plate contacting the main body, one end of the second gas flow groove being in communication with one end of the first penetrating portion opposite to the first heat-exchange plate, another end of the second gas flow groove being in communication with one side of the first guiding plate opposite to the main body;
a second guiding plate, having one side thereof connected with the side of the first guiding plate opposite to the main body, the second guiding plate comprising:
a third gas flow groove, disposed on the side of the second guiding plate connected with the first guiding plate, one end of the third gas flow groove being in communication with the end of the second gas flow groove opposite to the first penetrating portion; and
a fourth gas flow groove, disposed on one side of the second guiding plate opposite to the first guiding plate, one end of the fourth gas flow groove being in communication with one end of the second penetrating portion opposite to the first heat-exchange plate;
a second heat-exchange plate, disposed on the side of the second guiding plate opposite to the first guiding plate, so as to cover the fourth gas flow groove; and
a compressor, disposed in the insertion space and comprising:
a compression chamber, having a compression space therein, an gas inlet and an gas outlet being sequentially disposed on an outer side of the compression chamber, the gas inlet being in communication with one end of the third gas flow groove opposite to the second gas flow groove, the gas outlet being in communication with one end of the fourth gas flow groove opposite to the second penetrating portion;
a motor, disposed in the compression chamber;
a rotation shaft, having one end thereof connected with the motor, and another end thereof extending into the compression space, the rotation shaft being rotatably disposed on one side of the compression chamber contacting the compression space; and
a rotor, disposed in the compression space and connected with the rotation shaft, the rotation shaft being configured to rotate together with the rotor, so as to compress a gas fluid in the compression space, and deliver a compressed gas fluid from the gas outlet toward the fourth gas flow groove.

2. The heat dissipation system of claim 1, wherein the compressor comprises a stator, which is non-rotatably disposed in the compression space and arranged between the rotor and the motor, wherein the stator, the rotor, and an axis of the rotation shaft are disposed in a coaxial arrangement.

3. The heat dissipation system of claim 2, wherein the rotor comprises a rotor disc disposed on the rotation shaft, and a plurality of rotor blades; wherein each of the rotor blades is radially disposed around an outer peripheral side of the rotor disc, and a surface of each of the rotor blades is disposed in a twisted first arc surface; and
the stator comprises a stator disc through which the rotation shaft passes, and a plurality of stator blades; wherein each of the stator blades is radially disposed around an outer peripheral side of the stator disc, and a surface of each of the stator blades is disposed in a twisted second arc surface; wherein a twisting direction of the first arc surface is opposite to a twisting direction of the second arc surface.

4. The heat dissipation system of claim 1, wherein a recess is disposed on one side of the first heat-exchange plate opposite to the main body.

5. The heat dissipation system of claim 1, wherein a plurality of fins are disposed on one side of the second heat-exchange plate opposite to the second guiding plate, wherein the fins are disposed on the second heat-exchange plate at equal intervals along an extending direction.

6. The heat dissipation system of claim 1, wherein a fan is disposed on one side of the second heat-exchange plate opposite to the second guiding plate.

7. The heat dissipation system of claim 1, wherein an atomizer is disposed on one end of the second penetrating portion opposite to the first guiding plate.

8. The heat dissipation system of claim 1, wherein a seal plate is disposed on the main body and arranged in positional alignment with the third penetrating portion, so as to cover the insertion space.

9. The heat dissipation system of claim 1, wherein the charging valve is selectively connected to an gas exhaust device, so as to create a vacuum in the compression space, or connected to a refrigerant storage device, so as to fill the compression space with a refrigerant.

10. The heat dissipation system of claim 1, further comprising:
a first through hole passing through the first guiding plate to communicate two corresponding sides of the first guiding plate and arranged in communication with the third gas flow groove;
a second through hole passing through the main body and disposed in positional alignment with the first through hole and the gas inlet, so that the side of the main body opposite to the first heat-exchange plate is in communication with the insertion space and the compression space;
a third through hole passing through the main body and disposed in positional alignment with the gas outlet, so that the side of the main body opposite to the first heat-exchange plate is in communication with the insertion space and the compression space;
a fourth through hole passing through the first guiding plate to communicate the two opposite sides of the first guiding plate and disposed in positional alignment with the third through hole;
a fifth through hole passing through the second guiding plate to communicate two opposite sides of the second guiding plate, disposed in positional alignment with the fourth through hole, and arranged in communication with the fourth gas flow groove; and
a sixth through hole passing through the first guiding plate to communicate the two opposite sides of the first guiding plate, and disposed in positional alignment with the fourth gas flow groove and the second penetrating portion.
